(19) United States
(12) Patent Application Publication
(10) Pub. No.: US 2011/0226300 A1
(43) Pub. Date: Sep. 22, 2011

(54) DEVICE FOR RAPIDLY TRANSFERRING THERMAL ENERGY

(76) Inventor: Sascha Mantovani, Breganzona (CH)

(21) Appl. No.: 13/131,101

(22) PCT Filed: Nov. 25, 2008
(86) PCT No.: PCT/IB08/03231

§ 371 Date: May 25, 2011

(51) Int. Cl. H01L 35/30

(52) U.S. Cl. 136/205

(57) ABSTRACT

Device for rapidly transferring thermal energy from a heat source to a point of arrival at a velocity greater than the convective capacity of the adjacent element, enabling the thermal energy to be converted into electrical energy via a conversion device positioned at the point of arrival, the thermal energy being transferred via a coating composed of one or more nanomaterials with atoms which form an ordered geometrical structure.

The present invention relates to the technical field of the transfer of thermal energy from a heat source to another point.

The present invention concerns a device for transferring thermal energy which can be applied to any object in which a thermal gradient is found, as described in the preamble of Claim 1.

The discovery and manipulation of nanomaterials are creating renewed interest in applications which would not be feasible otherwise, due to the inefficiency of existing materials.

The term “nanotechnology” denotes the experimental procedures used for constructing objects, devices, materials, alloys and coatings whose dimensions are measured in billionths of a metre.

The term “nanomaterial” denotes a nanostructured material characterized by the fact that its nanostructure is designed and modified to provide a precise set of services.

Crystalline structures with dimensions of less than 100 nanometres have special characteristics which can be exploited at the macro-scale, by using special processing methods. Nanotechnology can be used to create new functional materials, tools and systems with extraordinary properties due to their molecular structure, and to provide qualities and characteristics of existing processes and products. This is because objects at the nano-scale can change their colour, shape and phase much more easily than at the macro-scale. Fundamental properties such as mechanical strength, the ratio between area and mass, conductivity and elasticity can be designed to create new classes of material which do not exist in nature.

There are essentially two approaches to the manufacture of these nanomaterials.

One is atomically controlled microscopy, developed at IBM by Binnig and Rohrer, who won the Nobel Prize for this work. The other is a bottom-up process, in which monolayers with dimensions measured in billionths of a metre are created, starting from organic materials such as conductive polymers, proteins or nucleic acids, and materials and devices suitable for a wide variety of applications are then built and assembled onto these.

The inventor's aim is to enable the heat stored in thermal or geothermal energy, or originating in any way therefrom, to be converted into electrical energy, regardless of whether the quantities of energy are minute or substantial, by means of a rapid transfer of thermal energy using a coating of nanomaterials.

There are known electronic devices which use two well-known physical phenomena, namely the Peltier effect and the Seebeck effect, to convert thermal energy to electrical energy and vice versa.

For efficient conversion of thermal energy to electrical energy, it must be possible to transfer the energy from a heat source to another point in the most efficient way possible without losses during the flow of thermal energy.

It is essential that the heat transfer should take place in the shortest possible time in order to ensure that other exchanges with the environment are negligible, as such exchanges would cause dissipation and consequently an undesirable loss of energy.

For this reason, the device is usually coated with a material having high thermal conductivity, which allows heat to flow in directions which can be determined by creating suitable thermal gradients.

Unfortunately, both the known coatings and the device in which convective or conductive fluids are used are characterized by high heat dissipation, and this has given rise to the inventor's idea of proposing an innovative device for heat transfer.

The term “conductivity” denotes the quantity of heat transferred in a direction perpendicular to a surface of unit area, due to a temperature gradient, within a unit of time and in specified conditions.

The transfer of thermal energy is caused solely by the temperature gradient T. In simple terms, this describes the ability of a substance to transmit heat.

As a general rule, thermal conductivity varies with electrical conductivity; metals have high values of both forms of conductivity. A noteworthy exception is that of diamond, which has high thermal conductivity but low electrical conductivity.

Thermal conductivity is known to be affected by the following factors:
the chemical composition of the material
the density of the material (kg/m³)
the molecular structure of the material

The principle of the invention is based on the modification of the molecular structure of the material.

The object of the present invention is to provide a device for transferring thermal energy, which can transfer thermal energy without inertia at a velocity greater than the convective capacity of the adjacent means, thus permitting efficient conversion to ordered energy, particularly electrical energy.

This object is achieved by the transfer device having the characteristics defined in Claim 1.

Advantageous developments of the device proposed by the invention are described in dependent claims 2-4.

The other principal advantages yielded by the present invention are as follows: greater thermal conductivity, the possibility of producing electricity, and better heat dissipation.

The invention will now be described more fully with reference to the attached drawing which is a schematic illustration of a practical embodiment of the invention, provided solely as a non-limiting example, since technical or constructional changes can be made at any time without departure from the scope of the present invention.

In said drawing,

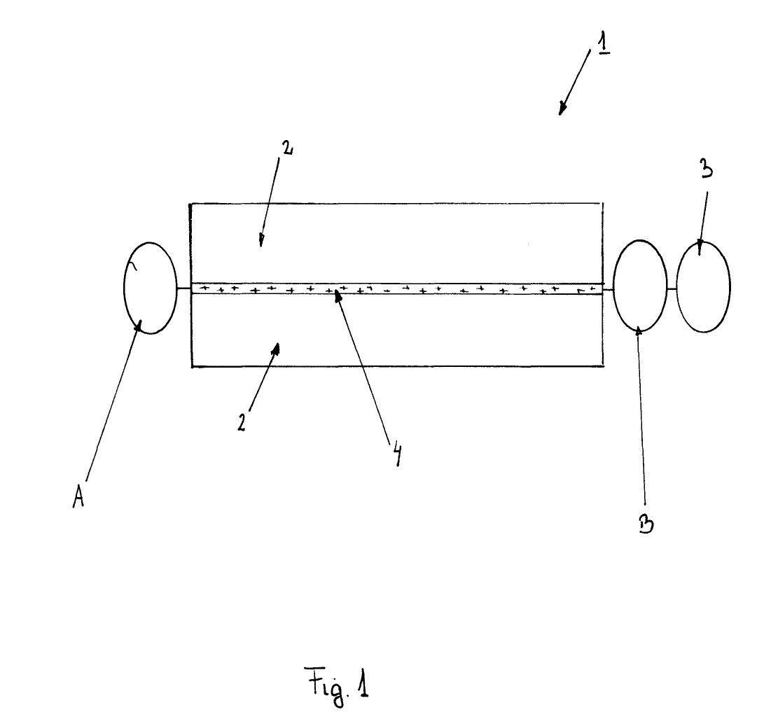

FIG. 1 is a schematic representation of what is proposed by the invention.

FIG. 1 shows a device 1 for transferring thermal energy from a heat source A to another point B at a velocity greater than the convective capacity of the adjacent means 2, thus enabling the thermal energy to be converted into electrical energy by means of a conversion device 3 positioned at the point of arrival B.

The device 1 in question transfers the thermal energy by means of a coating 4 composed of one or more nanomaterials having a geometrically ordered structure.

In one embodiment, the coating 4 advantageously has a nanometric thickness at the molecular level with atoms substituted for the original atoms present in the molecules concerned.

Such substitutions generate entirely novel alloys. The greater thermal conductivity is achieved as a result of the geometrical structure of the nanomaterials and also as a result of the type of atoms used, being a synergistic effect of both of the aforementioned factors.

Clearly, the device for transferring thermal energy as proposed by the invention can be used for numerous applications, namely all those in which heat transfer is required, in various fields, as follows: machine tools, electric motors, photovoltaic panels, and combustion engines.

1. Device (1) for rapidly transferring thermal energy from a heat source (A) to a point of arrival (B) at a velocity greater than the convective capacity of the adjacent means (2), enabling the thermal energy to be converted into electrical energy by means of a conversion device (3) positioned at the point of arrival (B), characterized in that said thermal energy is transferred by means of a coating (4) whose thickness varies according to the quantity of energy to be transferred and according to the process used to form the coating which is composed of one or more nanomaterials which reproduce, to the extent permitted by the coating method used, an ordered structure providing high thermal conductivity.

2. Device (1) for transferring thermal energy according to claim 1, in which the atoms are metallic.

3. Device (1) for transferring thermal energy according to claim 1, in which the atoms are non-metallic.

4. Device (1) for transferring thermal energy according to claim 1, characterized in that the device is provided with thermophotovoltaic means (5) for converting thermal energy into electrical energy.

5. Device (1) for transferring thermal energy according to claim 1, characterized in that it is provided with Peltier-Seebeck cells.

6. Device (1) for transferring thermal energy according to claim 2, characterized in that the device is provided with thermophotovoltaic means (5) for converting thermal energy into electrical energy.

7. Device (1) for transferring thermal energy according to claim 3, characterized in that the device is provided with thermophotovoltaic means (5) for converting thermal energy into electrical energy.

8. Device (1) for transferring thermal energy according to claim 2, characterized in that it is provided with Peltier-Seebeck cells.

9. Device (1) for transferring thermal energy according to claim 3, characterized in that it is provided with Peltier-Seebeck cells.
